(19) United States
(12) Patent Application Publication
(10) Pub. No.: US 2012/0049300 A1
(43) Pub. Date: Mar. 1, 2012

(54) SENSOR APPARATUS AND METHOD FOR MOUNTING SEMICONDUCTOR SENSOR DEVICE

(75) Inventors: Shinya YAMAGUCHI, Tokyo (JP); Tomohito Taki, Tokyo (JP); Takashi Usui, Tokyo (JP); Soichiro Suzu, Tokyo (JP)

(73) Assignee: MITSUMI ELECTRIC CO., LTD., Tokyo (JP)

(21) Appl. No.: 13/219,756

(22) Filed: Aug. 29, 2011

(30) Foreign Application Priority Data
Aug. 31, 2010 (JP) 2010-194636
Aug. 11, 2011 (JP) 2011-176062

(51) Int. Cl. H01L 29/84; H01L 21/50

(52) U.S. Cl. 257/417; 438/51; 257/E29.324; 257/E21.499

(57) ABSTRACT

A sensor apparatus includes a semiconductor sensor device including a first attachment surface, a base part being wire-bonded to the semiconductor sensor device and including a second attachment surface, and a spacer being interposed between the first and second attachment surfaces and having a target attachment surface to which at least one of the first and second attachment surfaces is adhered via a die-bond resin. A total area of the target attachment surface is smaller than a total area of the first attachment surface.

### BACKGROUND OF THE INVENTION

1. Field of the Invention

The present invention generally relates to a sensor apparatus including a semiconductor sensor device and a method for mounting the semiconductor sensor device.

2. Description of the Related Art

FIG. 1A is a plan view of a substrate 112 on which a semiconductor pressure sensor device 111 is mounted according to a related art example. FIG. 1B is a cross-sectional view of the substrate 112 and the semiconductor pressure sensor device 111 mounted on the substrate 112 according to a related art example. The semiconductor pressure sensor device 111 includes a diaphragm 111b and a frame part 111a supporting the diaphragm 111b from below. Further, wire-bonding pads 111c are formed on an upper surface of the semiconductor pressure sensor device 111. The substrate 112 includes a top surface (mounting surface) 112A and a bottom surface 112B. The top surface 112A of the substrate 112 is formed of a resist film 112A1. Bonding pads 114 are formed on the top surface 112A of the substrate 112. Reference numeral 151 represents a resist film removal surface exposed by removing the resist film 112A1 formed on a predetermined part of the top surface 112A of the substrate 112. Reference numeral 112D indicates a base material of the substrate 112. In a case of fixing a stress detecting device such as the semiconductor pressure sensor device 111 onto the substrate 112, a die-bond resin 115 having a low elastic coefficient is often used as an adhesive agent as illustrated in FIGS. 1A and 1B for absorbing/buffering the stress applied to the substrate 112 from the outside of the substrate 112 or the stress caused by the difference of thermal expansion coefficients between the semiconductor pressure sensor device 111 and substrate 112.

However, in a case of ball-bonding a bonding wire 113 to the semiconductor pressure sensor device 111 being die-bonded to the substrate 112 via the die-bond resin 115 for establishing electric connection between the substrate 112 and the semiconductor pressure sensor device 111, the wire bonding strength (ability to bond) of the bonding wire 113 decreases due to the die-bond resin 115 acting as a buffer material. For example, the bonding wire 113 is adhered to the semiconductor pressure sensor device 113 by transmitting ultrasonic waves, force (load), and heat from a capillary 100 to a wire ball 113a provided at the tip of the bonding wire 113, as illustrated in FIG. 2. However, in the case of adhering (wire-bonding) the bonding wire 113 to the semiconductor pressure sensor device 111, the semiconductor pressure sensor device 111 tilts downward toward one side when force is applied to the semiconductor pressure sensor device 111 due to the semiconductor pressure sensor device 111 fixed to the substrate 112 by the die-bond resin 115 having a low elastic coefficient. Thereby, ultrasonic waves and force cannot be sufficiently transmitted. As a result, problems such as decrease of wire-bonding strength may occur.

As illustrated in FIG. 3, there are related art examples (e.g., Japanese Laid-Open Patent Application Nos. 7-45642, 63-233342) where beads (filler) 115a are blended into the die-bond resin 115 for increasing bonding strength.

However, the die-bond resin having beads blended therein may cause a needle of a die-bond resin supplying dispenser to clog. Further, by blending beads into a die-bond resin, the applicability (coating property) of the die-bond resin may be degraded. Further, operability and productivity may be degraded due to management difficulty (e.g., difficulty in storing the die-bond resin or controlling dispersion of the beads) and cost may increase because beads are blended into a die-bond resin.

### SUMMARY OF THE INVENTION

The present invention provides a sensor apparatus including a semiconductor sensor device and a method for mounting the semiconductor sensor device that substantially eliminate one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided in the description. Objects as well as other features and advantages of the present invention will be realized and attained by a sensor apparatus including a semiconductor sensor device and a method for mounting the semiconductor sensor device particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the present invention provides a sensor apparatus including: a semiconductor sensor device including a first attachment surface; a base part being wire-bonded to the semiconductor sensor device and including a second attachment surface; and a spacer being interposed between the first and second attachment surfaces and having a target attachment surface to which at least one of the first and second attachment surfaces is adhered via a die-bond resin; wherein a total area of the target attachment surface is smaller than a total area of the first attachment surface.

Other objects and further features of the present invention will be apparent from the following detailed description when read in conjunction with the accompanying drawings.

### BRIEF DESCRIPTION OF THE DRAWINGS

FIG. 1A is a plan view illustrating a pressure sensor apparatus according to a related art example;

FIG. 1B is a cross-sectional view illustrating the pressure sensor device according to a related art example;

FIGS. 2A and 2B are schematic diagrams for describing a method for mounting a semiconductor pressure sensor according to a related art example;

FIG. 3 is a cross-sectional view illustrating a pressure sensor apparatus according to a related art example;

FIG. 4 is a cross-sectional view of a circuit board and a pressure sensor device mounted on the circuit board according to an embodiment of the present invention;

FIGS. 5A-5C are schematic diagrams illustrating an outer configuration of a substrate according to an embodiment of the present invention;

FIG. 6 is a flowchart for describing a method for mounting a semiconductor pressure sensor device according to an embodiment of the present invention;

FIGS. 7A and 7B are schematic diagrams for describing a step of applying a die-bond resin in the flowchart of FIG. 6 according to an embodiment of the present invention;

FIGS. 8A and 8B are schematic diagrams for describing a step of die-bonding and a step of wire-bonding in the flowchart of FIG. 6 according to an embodiment of the present invention;

FIG. 9 is a graph illustrating results of measuring the wire-bonding strength in a case where a resist spacer is used and a case where a resist spacer is not used;

FIG. 10 is a schematic diagram illustrating a resist spacer having a hollow square shape according to an embodiment of the present invention;

FIG. 11 is a schematic diagram illustrating resist spacers formed in positions facing four corners of an attachment surface of a frame part according to an embodiment of the present invention;

FIG. 12 is a schematic diagram illustrating resist spacers in which the area of a target attachment surface of each of the resist spacers is small according to an embodiment of the present invention;

FIG. 13 is a schematic diagram illustrating a resist spacer that extends from a pressure inlet in radial directions according to an embodiment of the present invention;

FIG. 14 is a schematic diagram illustrating a resist spacer having a hollow circle shape according to an embodiment of the present invention;

FIG. 15 is a schematic diagram illustrating a metal spacer according to an embodiment of the present invention;

FIG. 16 is a cross-sectional view illustrating a sensor apparatus according to another embodiment of the present invention; and

FIG. 17 is a cross-sectional view of a sensor apparatus according to yet another embodiment of the present invention.

### DESCRIPTION OF THE PREFERRED EMBODIMENTS

In the following, embodiments of the present invention will be described with reference to the accompanying drawings. Although an example of a semiconductor pressure sensor device is described in the following description of the embodiments of the present invention, the present invention may be applied to other sensor devices using semiconductor technology. For example, the present invention may also be applied to an acceleration sensor or a semiconductor microphone.

FIG. 4 is a cross-sectional view of a circuit board 21 and a sensor apparatus 2 (e.g., pressure sensor apparatus) mounted on the circuit board 21 according to an embodiment of the present invention. The sensor apparatus 2 of this embodiment has a structure in which a semiconductor pressure sensor device 11 is packaged inside a housing 16. The semiconductor pressure sensor device 11 is adhered to a mounting surface 12A of a substrate (base part) 12 by using a die-bond resin (e.g., silicon resin) as an adhesive agent. The sensor device 2 is fixed to a target attachment surface (front surface) 21A of the circuit board 21. In this embodiment, a terminal 19 provided on an attachment surface 12B of the substrate 12 and a land (not illustrated) provided on the target attachment surface 21A of the circuit board 21 are soldered together with a solder 32. The circuit board 21 is, for example, a substrate of an electronic device such as a pressure meter that utilizes data of the pressure detected from the pressure sensor device. The circuit board 21 includes the target attachment surface 21A and a rear surface 21B formed on the side opposite to the target attachment surface 21A.

The substrate 12 is a base part of the sensor device 2 for fixing the semiconductor pressure sensor device 11 thereto. The substrate 12 includes the mounting surface 12A on which the semiconductor pressure sensor device 11 is mounted. In this embodiment, the semiconductor pressure sensor device 11 and a bonding pad 14 formed on the mounting surface 12A are wire-bonded with a bonding wire 13. The semiconductor pressure sensor device 11 is installed in the housing 16 adhered to the mounting surface 12A with an adhesive agent (e.g., epoxy resin) 31.

The housing 16 includes a pressure supply port 17 having a tube-like shape. The semiconductor pressure sensor device 11 detects pressure (target pressure), for example, fluid pressure of a gas supplied from the pressure supply port 17. The semiconductor pressure sensor device 11 includes a diaphragm 11b that detects pressure. The semiconductor pressure sensor device 11 may be, for example, a semiconductor strain gauge type device that detects change of a resistance value corresponding to the deformation (strain) of the diaphragm 11b. Alternatively, the semiconductor pressure sensor device 11 may be, for example, an electrostatic type device that detects change of electrostatic capacity corresponding to the displacement of the diaphragm 11b. Other types of devices for detecting the target pressure may be used. The semiconductor pressure sensor device 11 has the diaphragm lib interposed between the pressure supply port 17 of the housing and a pressure inlet 18 of the substrate 12. Accordingly, the diaphragm 11b is positioned below the pressure supply port 17 and above a pressure inlet 18. The deformation (or displacement) of the diaphragm 11b changes in correspondence with the pressure difference between the target pressure applied from the pressure supply port 17 and the ambient pressure applied from the pressure inlet 18. Accordingly, by determining the detected amount of deformation (or amount of displacement) as the change of resistance value (or electrostatic capacity value), the target pressure can be measured.

The semiconductor pressure sensor device 11 includes the diaphragm 11b and a frame part 11a supporting the diaphragm 11b from below. The frame part 11a is formed at a periphery of a bottom surface (i.e. surface toward the pressure inlet 18) of the diaphragm 11b in a manner encompassing four sides of the bottom surface and extending toward the mounting surface 12A of the substrate 12. It is to be noted that a portion of the frame part 11a is not illustrated in FIG. 4 for the sake of convenience. In this embodiment, the frame part 11a has a hollow square shape. The semiconductor pressure sensor device 11 is mounted on the substrate 12 by die-bonding the frame part 11a to the mounting surface 12A with the die-bond resin 15. Details of mounting the semiconductor pressure sensor device 11 on the substrate 12 are described below.

The pressure inlet 18 is a first through-hole formed between the mounting surface 12A and the attachment surface 12B. A pressure inlet 22 is a second through-hole formed between the target attachment surface 21A and the rear surface 21B. The aperture diameter of the pressure inlet 22 is larger than the aperture diameter of the pressure inlet 18. The sensor apparatus 2 is mounted on the surface of the circuit board 21 by positioning the attachment surface 12B and the target attachment surface 21A face to face and soldering the terminal 19 to the target attachment surface 21A with the solder 32 in a manner where the pressure inlet 18 and the pressure inlet 22 are in communication. Thereby, atmospheric pressure outside of the housing 16 can be guided and applied to the diaphragm 11b of the semiconductor pressure sensor device 11.

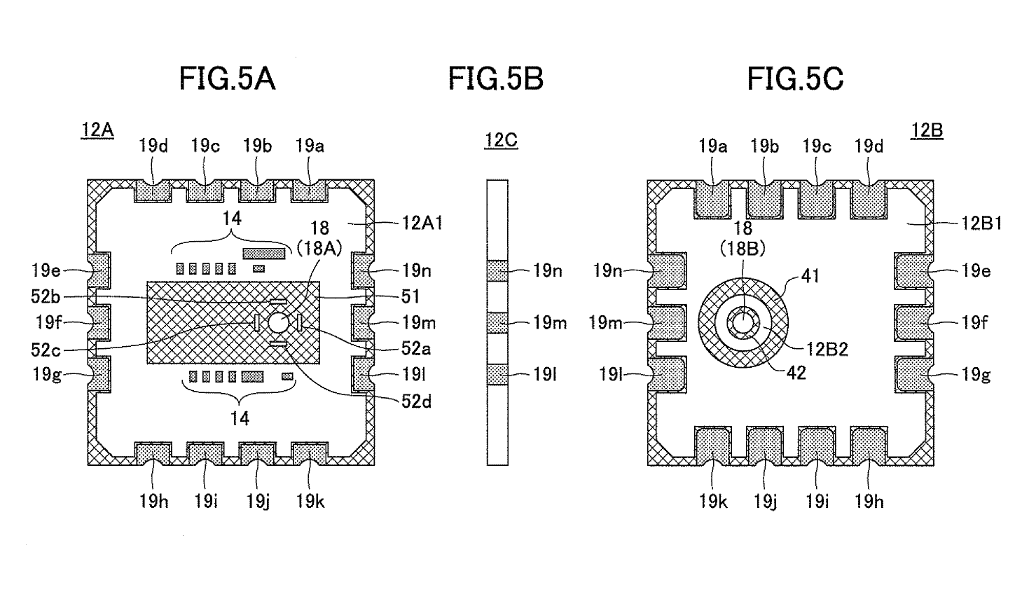

As illustrated in FIGS. 4 and 5C, the substrate 12 includes a step part 41 having, for example, a hollow circle (concave) shape. The step part 41 is formed between a resist removal part 42 (a portion tangential to the pressure inlet 18) and the terminals 19 by removing a portion of resin film 12B1 formed on the attachment surface 12B. Owing to the step part 41 formed in this manner, liquefied flux of the solder 32 applied to the terminal 19 on the attachment surface 12B can be prevented from flowing along the attachment surface 12B and blocking an opening part of the pressure inlet 18 in a case of soldering the sensor apparatus 2 to the circuit board 21.

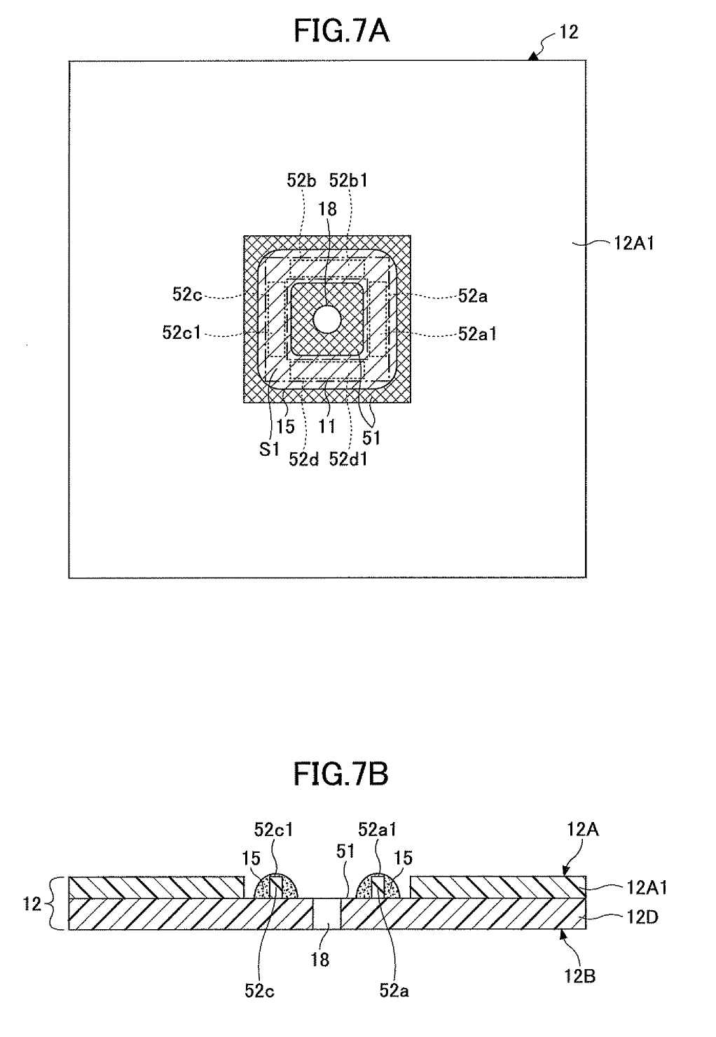

FIGS. 5A-5C are schematic diagrams illustrating an outer configuration of the substrate 12 according to an embodiment of the present invention. FIG. 5A is a plan view of the substrate 12 (i.e. the substrate 12 being observed from the side of the mounting surface 12A of the substrate 12). FIG. 5B is a side view of the substrate 12 (i.e. the substrate 12 being observed from the side of a side surface 12C of the substrate 12). FIG. 5C is a bottom view of the substrate 12 (i.e. the substrate 12 being observed from the side of the attachment surface 12B of the substrate 12. The material of the substrate 12 is, for example, FR-4. The matte pattern parts illustrated in FIGS. 5A-5C represent gold-plated parts having no resist film formed thereon. The lattice pattern parts illustrated in FIGS. 5A and 5C represent a part of a base material 12D (see, for example, FIG. 7B) of the substrate 12 having no resist film or copper foil formed thereon. Reference numerals 12A1, 12B1, and 12B2 in FIGS. 5A and 5C represent resist films formed on the surface of the base material 12D. Plural of the terminals 19 (19a-19n) are formed at peripheral parts of the substrate 12 and electrically connected to corresponding bonding pads 14 via a wiring pattern (not illustrated). Each of the terminals 19 is formed in a manner spanning from the mounting surface 12A to the attachment surface 12B via the side surface 12C.

One or more resist spacers 52 (52a, 52b, 52c, 52d) serve as pedestals on which the frame parts 11a of the semiconductor pressure sensor device 11 are mounted. The resist spacers 52 are convex parts positioned between the opening part 18A and the terminals 19 by removing a predetermined part of the resist film 12A1 formed on the mounting surface 12A. Reference numeral 51 represents a resist film removal surface exposed by removing the resist film 12A1 formed on the predetermined part of the mounting surface 12A. In other words, the resist spacers 52 are formed in a manner protruding from the resist film removal surface 51, provided at a periphery of the opening part 18A of the pressure inlet 18, and positioned a predetermined distance apart from the opening part 18A. By positioning the resist spacers 52 a predetermined distance apart from the opening part 18A, the die-bond resin 15 can be prevented from flowing toward and reaching the opening part 18A in a case of applying the die-bond resin 15 to the resist spacers 52 for adhering the semiconductor pressure sensor device 11 to the resist spacers 52. Thereby, the pressure inlet 18 can be prevented from being blocked by the die-bond resin 15. Further, by positioning the resist spacers 52 apart from each other at substantially equal intervals at the periphery of the opening part 18A of the pressure inlet 18, the semiconductor pressure sensor device 11 can be stably adhered to each of the resist spacers 52.

Considering aspects such as the viscosity of the die-bond resin 15, it is preferable for the height (thickness) of the resist spacer 52 to be equal to or less than the thickness of the layer of die-bond resin 15 applied during a regular die-bonding process (e.g., the layer of die-bond resin 15 having a thickness 20 μm or more and 30 μm or less). However, the preferable height (thickness) of the resist spacer 52 may change depending on, for example, the viscosity of the die-bond resin 15, the wettability of the die-bond resin 15, and the force applied to the die-bond resin 15.

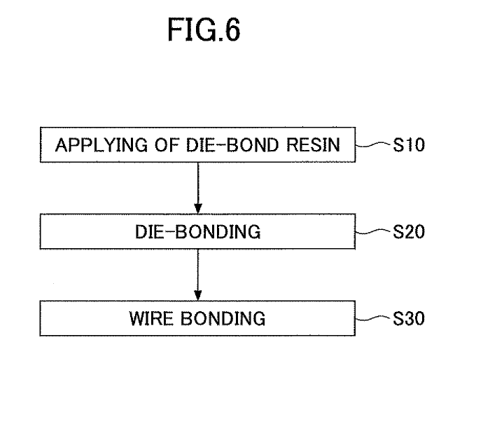

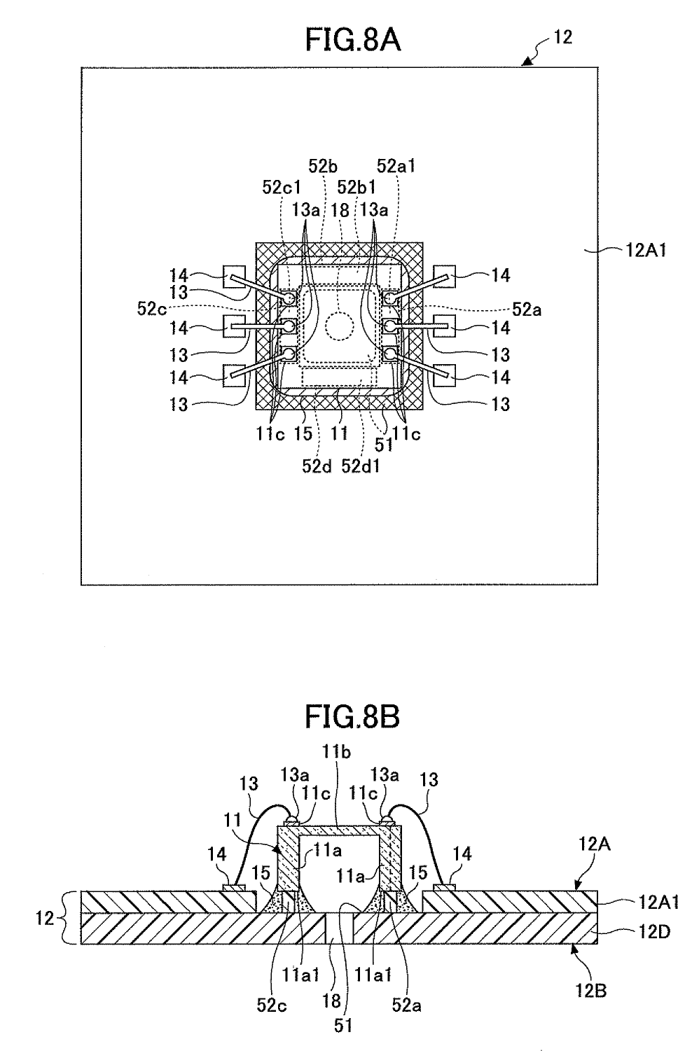

Next, an exemplary method for mounting the semiconductor pressure sensor device 11 on the substrate 12 provided with the resist spacers 52 is described with reference to FIGS. 6, 7A, 7B, 8A, and 8B. FIG. 6 is a flowchart for describing a method for mounting the semiconductor pressure sensor device 11 according to an embodiment of the present invention. FIGS. 7A and 7B are schematic diagrams for describing a step of applying a die-bond resin (Step S10) in the flowchart of FIG. 6 according to an embodiment of the present invention. FIGS. 8A and 8B are for describing a step of die-bonding (Step S20) and a step of wire-bonding in the flowchart of FIG. 6 according to an embodiment of the present invention. FIGS. 7A and 8A are plan views of the substrate 12 on which the semiconductor pressure sensor device 11 is mounted according to an embodiment of the present invention. FIGS. 7B and 8B are cross-sectional views of the substrate 12 and the semiconductor pressure sensor device 11 mounted on the substrate 12 according to an embodiment of the present invention.

In the step of applying the die-bond resin (Step S10 of FIG. 6), the die-bond resin 15 is applied from above the resist spacers 52. As illustrated in FIG. 7B, the resist spacers 52 are entirely covered by the die-bond resin 15. In this step, the conditions for applying the die-bond resin 15 are the same as the conditions used in a regular die-bonding process. In FIG. 7A, the area illustrated with diagonal lines represents an area where the die-bond resin 15 is applied to the resist spacers 52. Thus, by the applying of the die-bond resin 15, the die-bond resin 15 is formed on target attachment surfaces (upper surfaces) 52a1, 52b1, 52c1, and 52d1 of the resist spacers 52a, 52b, 52c, and 52d.

Then, in the step of die-bonding (Step S20 of FIG. 6), an attachment surface 11a1 (bottom surface) of the frame part 11a is adhered to the target attachment surfaces 52a1, 52b1, 52c1, and 52d1 via the die-bond resin 15 as illustrated in FIG. 8B.

Next, in the step of wire-bonding (Step S30 of FIG. 6), a wire-bonding pad 11c formed on an upper surface of the semiconductor pressure sensor device 11 is wire-bonded to the corresponding wire-bonding pad 14 with the bonding wire 13 as illustrated in FIG. 8A.

First, a wire-ball 13a is formed on a tip of the bonding wire 13 that is supplied from a capillary (not illustrated). The wire-ball 13a is positioned into contact with the wire-bonding pad 11c. By applying ultrasonic waves, force, and heat to the wire-ball 13a in the state contacting the wire-bonding pad 11c, the wire-ball 13a and the wire-bonding pad 14 become wire-bonded to each other. Then, the capillary is placed onto the wire-bonding pad 14. By applying ultrasonic waves, force, and heat to the bonding wire 13, the bonding wire 13 and the wire-bonding pad 14 become wire-bonded to each other.

The wire-bonding pad 11c is formed at a peripheral part of the diaphragm 11b on the upper surface of the semiconductor pressure sensor device 11. As illustrated in FIG. 8A, in a case where an outer structure of the wire-bonding pads 11c is projected from an upper surface of the semiconductor pressure sensor device 11, the projected area of the wire-bonding pads 11c superposes, for example, the target attachment surfaces 52a1-52d1 of the resist spacers 52a-52d. In other words, the wire-bonding pads 11c are formed at the peripheral part of the diaphragm 11b in a manner such that the wire-bonding pads 11c are positioned on a line normal to at least one of the target attachment surfaces 52a1-52d1 in a state where the semiconductor pressure sensor device 11 is mounted on the substrate 12. An example of the line normal to the target attachment surfaces 52c1 is illustrated with a dotted line in FIG. 8B. From an aspect of attaining greater die-bonding strength, it is more preferable for the target attachment surfaces 52a1-52d1 to be positioned within the projected area than merely superposed by projected area.

The semiconductor pressure sensor device 11a may incline downward (sink) toward one side when applying ultrasonic waves, force, and heat during a wire-bonding step if the die-bond resin 15 (having a low elastic coefficient (e.g., 1 MPa or less)) provided between the attachment surface 11a1 and the target attachment surface 52a1 is too thick. This results in problems such as loss of wire-bonding strength.

In contrast, with the above-described embodiment of the present invention, even in a case where die-bond resin 15 is excessively applied to the target attachment surfaces 52a1, 52b1, 52c1, 52d1 in the die-bonding step, the excess die-bond resin 15 will flow down from the target attachment surfaces 52a1, 52b1, 52c1, 52d1 to the resist film removal surface 51 (positioned at a lower level than the target attachment surfaces 52a1, 52b1, 52c1, 52d1) and escape (guided) to the side of the resist spacers 52 owing to the pedestal configuration (shape) of the resist spacers 52 on the resist film removal surface 51. As a result, the die-bond resin 15 applied to the target attachment surfaces 52a1, 52b1, 52c1, 52d1 can be prevented from becoming too thick. Accordingly, the semiconductor pressure sensor device 11 can be prevented from sinking and the wire-bonding strength can be prevented from decreasing even where ultrasonic waves, force, and heat are applied to the wire-ball 13a during a wire-bonding step.

Further, the target attachment surfaces 52a1, 52b1, 52c1, 52d1 are formed in a size so that an area S1 of the attachment surface 11a1 is larger than the total area S2 of the target attachment surfaces 52a1, 52b1, 52c1, 52d1 (i.e. sum of the areas of the target attachment surfaces 52a1, 52b1, 52c1, 52d1). In other words, the total area S2 of the target attachment surfaces 52a1, 52b1, 52c1, 52d1 is smaller than the area S1 of the attachment surface 11a1. The attachment surface 11a1 has a hollow square shape and an even flat surface. The hollow square portion S1 surrounded by a dot-dash line in FIG. 7A represents the area of the attachment surface 11a1. By forming the target attachment surfaces 52a1, 52b1, 52c1, 52d1 so that the total area S2 of the target attachment surfaces 52a1, 52b1, 52c1, 52d1 is smaller than the area S1 of the attachment surface 11a1, a space can be formed below the attachment surface 11a1. That is, because the total area S2 of the target attachment surfaces 52a1, 52b1, 52c1, 52d1 is smaller than the area of the attachment surface 11a1, the die-bond resin 15 can flow down from the resist film removal surface 51 and escape to the side of the resist spacers 52 (i.e. the space below the attachment surface 11a1) when attaching the attachment surface 11a1 to the target attachment surfaces 52a1, 52b1, 52c1, 52d1 via the die-bond resin 15 during the die-bonding step. As a result, the thickness of the die-bond resin 15 between the attachment surface 11a1 and the target attachment surfaces 52a1, 52b1, 52c1, 52d1 can be prevented from becoming thicker than necessary. Accordingly, the semiconductor pressure sensor device 11 can be prevented from sinking and the wire-bonding strength can be prevented from decreasing even where ultrasonic waves, force, and heat are applied to the wire-ball 13a during the wire-bonding step.

Further, the pressure applied to the die-bond resin 15 sandwiched between the attachment surface 11a1 and the target attachment surfaces 52a1, 52b1, 52c1, 52d1 during the die-bonding step is higher when the total area S2 of the target attachment surfaces 52a1, 52b1, 52c1, 52d1 is smaller than the area S1 of the attachment surface 11a1 compared to when the total area S2 of the target attachment surfaces 52a1, 52b1, 52c1, 52d1 is larger than the area S1 of the attachment surface 11a1. This is because, the stress applied to the target attachment surfaces 52a1, 52b1, 52c1, 52d1 increases under a condition in which the pressure applied from the semiconductor pressure sensor device 11 to the substrate 12 during the die-bonding step is substantially the same between a case where the total area S2 of the target attachment surfaces 52a1, 52b1, 52c1, 52d1 is smaller than the area S1 of the attachment surface 11a1 and a case where the total area S2 of the target attachment surfaces 52a1, 52b1, 52c1, 52d1 is larger than the area S1 of the attachment surface 11a1. Thus, the thickness of the die-bond resin 15 sandwiched between the attachment surface 11a and the target attachment surfaces 52a1, 52b1, 52c1, 52d1 can be reduced by forming the target attachment surfaces 52a1, 52b1, 52c1, 52d1 so that the total area S2 of the target attachment surfaces 52a1, 52b1, 52c1, 52d1 is smaller than the area S1 of the attachment surface 11a1. Thereby, the semiconductor pressure sensor device 11 can be prevented from sinking and the wire-bonding strength can be prevented from decreasing even where ultrasonic waves, force, and heat are applied to the wire-ball 13a during the wire-bonding step.

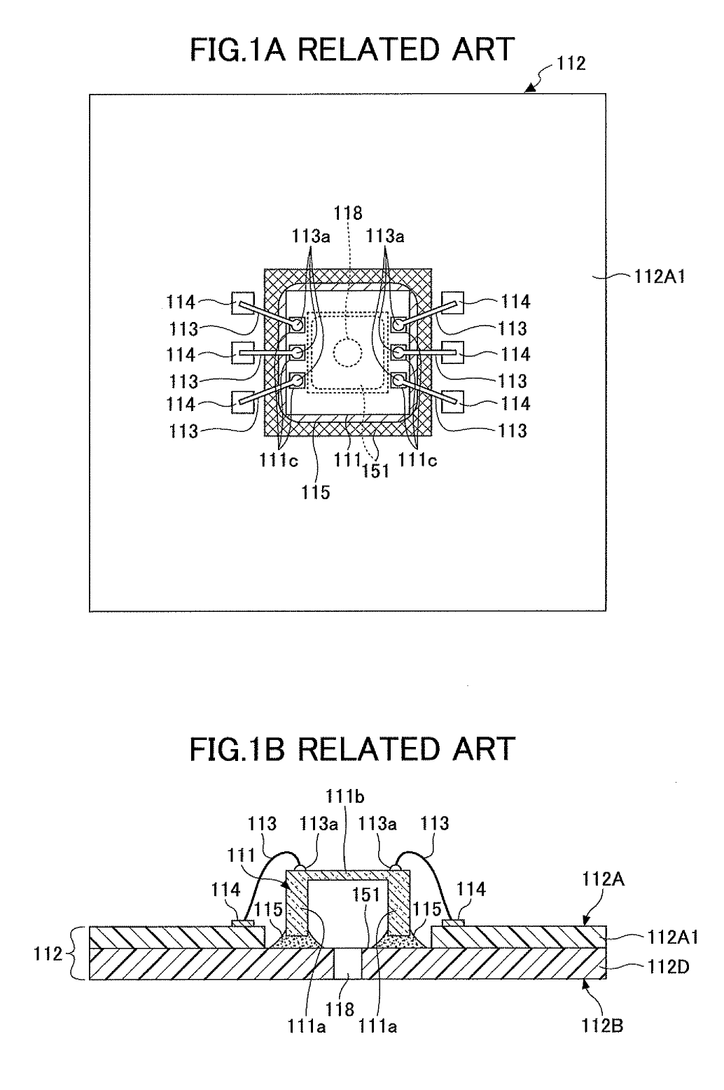

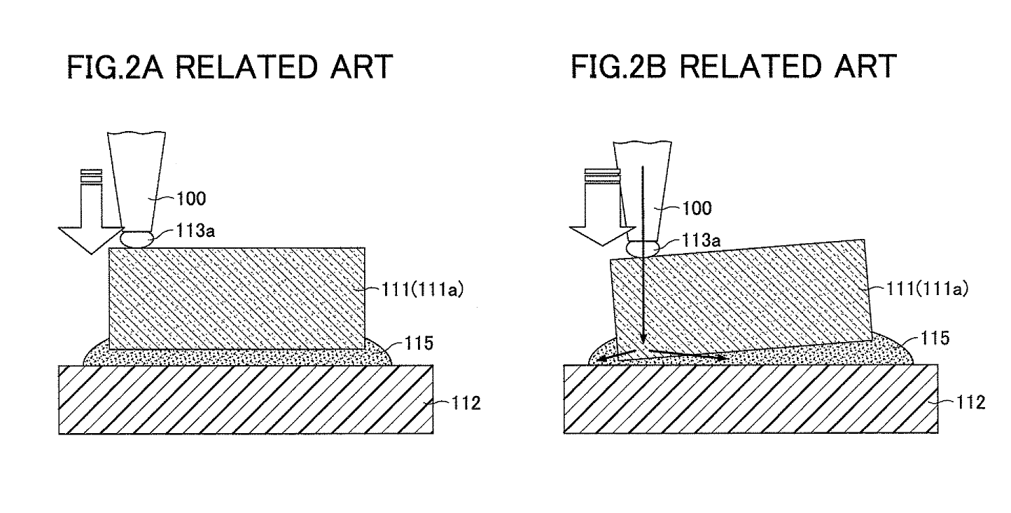

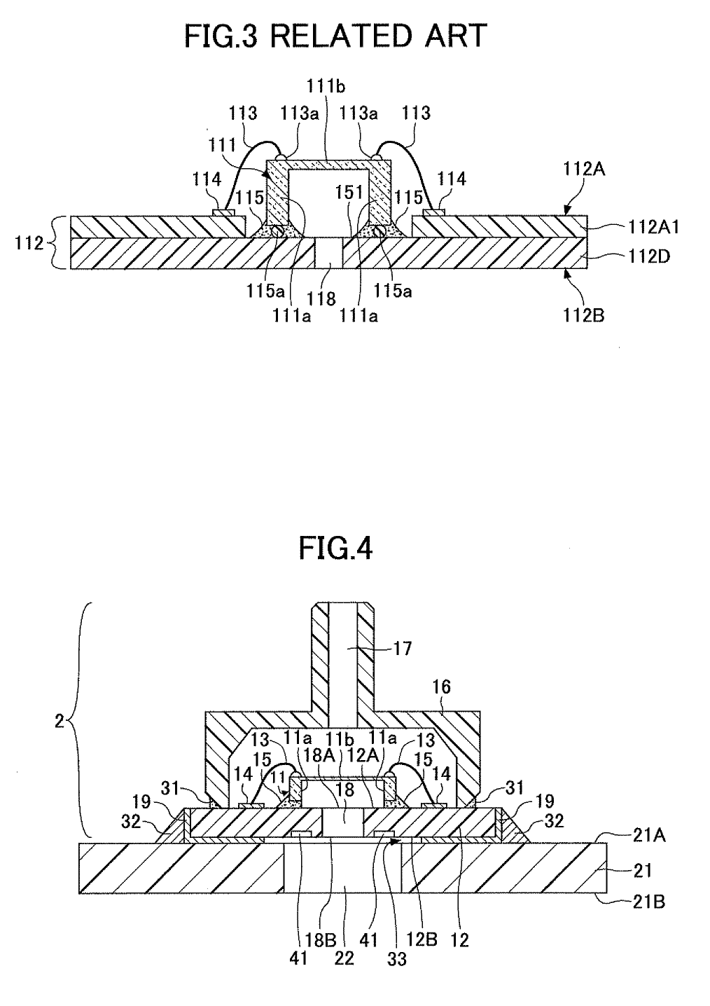

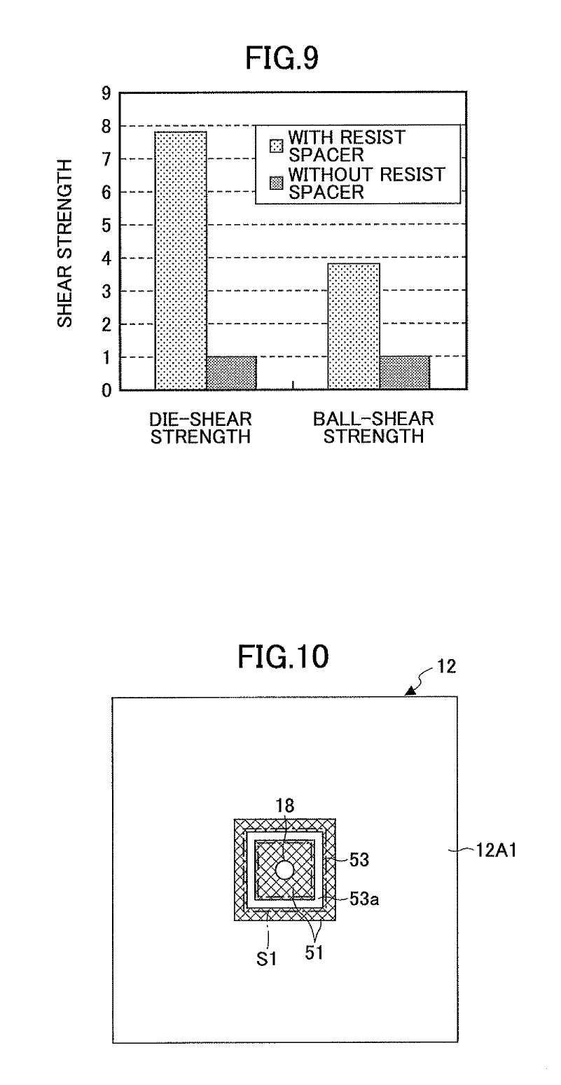

FIG. 9 is a graph illustrating results of measuring the wire-bonding strength in a case where the resist spacers 52 are used and a case where the resist spacers 52 are not used. The conditions for mounting the semiconductor pressure sensor device 11 on the substrate 12 where the spacers 52 are provided (e.g., FIGS. 7A-8B) and the conditions for mounting the semiconductor pressure sensor device 111 on the substrate 112 where the spacers 52 are not provided (e.g., FIG. 1) are the same when measuring the die-strength (bonding strength) between the semiconductor sensor device 11 and the substrate 12 and the ball-shear strength (bonding strength) between the semiconductor pressure sensor device 11 and the substrate 12 as illustrated in FIG. 9. As illustrated in FIG. 9, in the case where the spacers 52 are provided, the die-shear strength increases approximately 8 times and the ball-shear strength increases approximately 4 times compared to the case where no spacer 52 is provided.

Further, by forming the target attachment surfaces 52a1, 52b1, 52c1, 52d1 so that the total area S2 of the target attachment surfaces 52a1, 52b1, 52c1, 52d1 is smaller than the area S1 of the attachment surface 11a1, the area in which the attachment surface 11a1 contacts the mounting surface 12A of the substrate 12 becomes smaller. Thus, because the contacting area between the semiconductor pressure sensor device 11 becomes smaller, the effect of absorbing/buffering the stress applied to the substrate 12 from the outside or the stress caused by the difference of thermal expansion coefficients between the semiconductor pressure sensor device 11 and substrate 12 increases. Thereby, the detection accuracy of the semiconductor pressure sensor device 11 increases.

Further, with the above-described embodiment of the present invention, there is no need to blend beads into the die-bond resin 15. Thereby, manufacturing cost can be reduced. Further, because no beads are needed to be blended into the die-bond resin 15, the conditions for applying the die-bond resin 15 need not be changed compared to the conditions of a typical process of applying a die-bond resin. Further, compared to a case of using a resin containing beads (beads-containing resin) where the beads contained inside the resin are unstable, the configuration of the above-described embodiment of the present invention can steadily and consistently provide the functions of a spacer (pedestal). Further, compared to the case of using the beads containing resin, a greater bonding strength can be attained. Further, the accuracy for controlling the pressure during the die-bonding step can be simplified because there is no need to take the crushing/grinding of the beads into consideration.

Further, owing to the above-described pedestal configuration formed by removing the resist film of the substrate 12, the semiconductor pressure sensor device 11 can be manufactured without requiring an additional component such as a glass spacer. Accordingly, the semiconductor pressure sensor device 11 having a simple configuration can be manufactured.

Alternatively, other examples having a pedestal configuration may be used as the resist spacer 52 having a pedestal configuration including a target attachment surface to which the attachment surface 11a1 of the frame part 11a of the semiconductor pressure sensor device 11 is attached via the die-bond resin 15, as illustrated in FIGS. 10-15. All of the examples illustrated in FIGS. 10-15 include a target attachment surface having a total area S2 that is smaller than the area S1 of the attachment surface 11a1 of the frame part 11a of the semiconductor pressure sensor device 11.

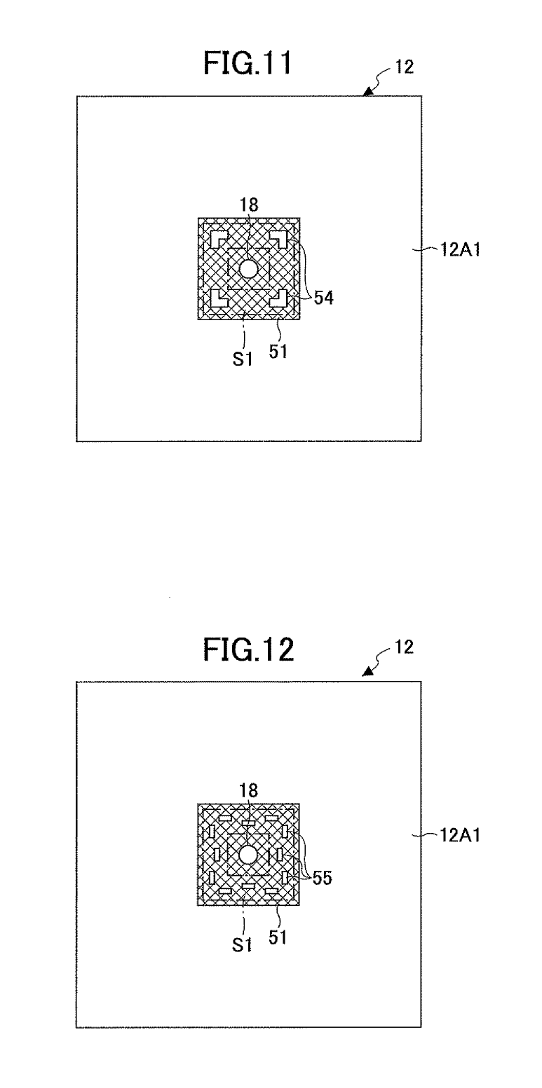

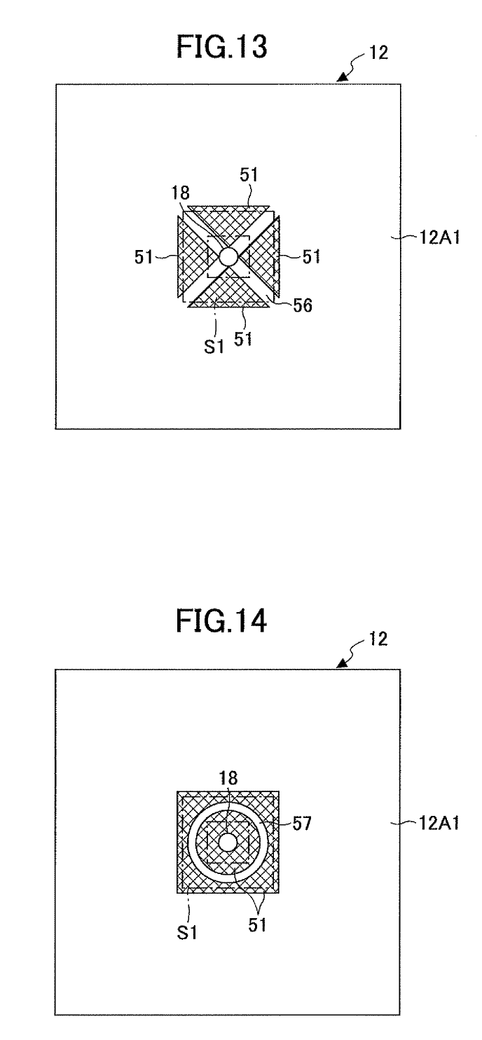

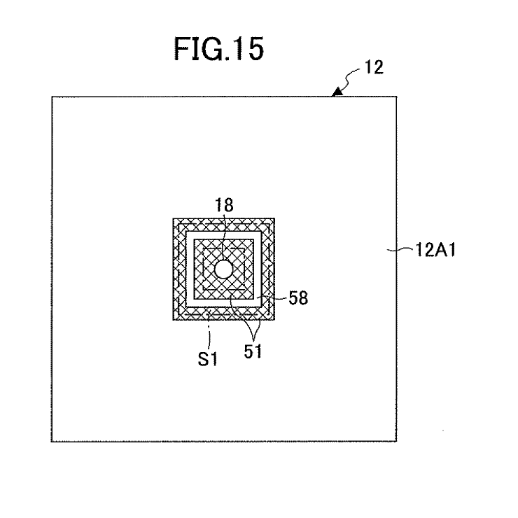

FIG. 10 is a schematic diagram illustrating a resist spacer 53 having a hollow square shape according to an embodiment of the present invention. By forming the resist spacer 53 in the shape illustrated in FIG. 10, wire-bonding strength can be improved. Because the die-bond resin 15 interposed between the target attachment surface 53a and the attachment surface 11a1 adheres along the resist spacer 53, the die-bond resin 15 can easily flow toward the pressure inlet 18. FIG. 11 is a schematic diagram illustrating resist spacers 54 formed in positions facing four corners of the attachment surface 11a1 of the frame part 11a according to an embodiment of the present invention. FIG. 12 is a schematic diagram illustrating resist spacers 55 in which the area of the target attachment surface of each resist spacer 55 is small compared to, for example, the area of the target attachment surface 52a1, 52b1, 52c1, 52d1 of each of the above-described resist spacers 52 according to an embodiment of the present invention. FIG. 13 is a schematic diagram illustrating a resist spacer 56 that extends from the pressure inlet 18 in radial directions according to an embodiment of the present invention. Owing to the radial configuration of the resist spacer 56, a large range of permissible error can be attained in a case where the position in which the semiconductor pressure sensor device 11 is mounted has deviated from an intended mounting position. FIG. 14 is a schematic diagram illustrating a resist spacer 57 having a hollow circle shape according to an embodiment of the present invention. By forming the resist spacer 57 in the shape illustrated in FIG. 14, the die-bond resin 15 interposed between the target attachment surface 53a and the attachment surface 11a1 adheres along the resist spacer 57. Thereby, the die-bond resin 15 can easily flow toward the pressure inlet 18. FIG. 15 is a schematic diagram illustrating a metal spacer 58. The metal spacer 58 is formed with a metal material instead of the above-described resin film. For example, the metal spacer 58 may be formed with a copper foil of the inner layer of the substrate 12. Alternatively, the metal spacer 58 may be formed by applying a metal material (e.g., gold plating) to the substrate 12.

Hence, with the sensor apparatus and the method for mounting the semiconductor pressure sensor device according to an embodiment of the present invention, wire bonding strength can be increased without having to blend beads into a die-bond resin used in, for example, mounting the semiconductor pressure sensor device.

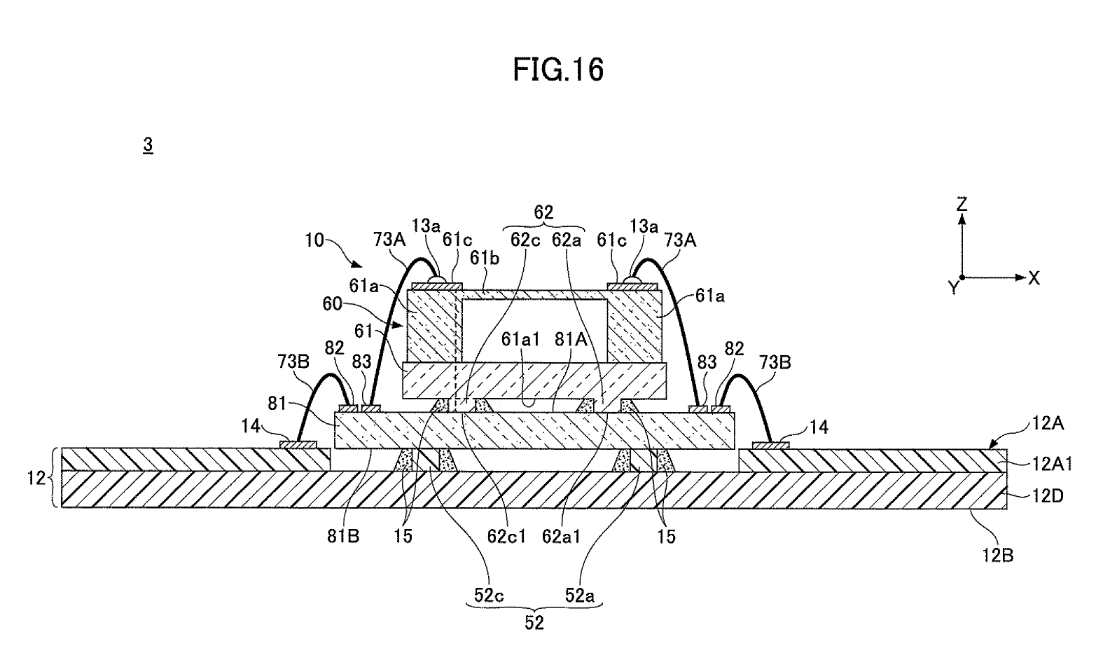

FIG. 16 is a cross-sectional view illustrating the sensor apparatus 3 (e.g., pressure sensor apparatus) according to an embodiment of the present invention. In FIG. 16, like components are denoted with like reference numerals as those of the above-described embodiments of the present invention and are not further explained. The sensor apparatus 3 has a stacked structure adhered to the substrate 12 via the die-bond resin 15. The stacked structure includes a semiconductor circuit device substrate 81 and the semiconductor pressure sensor device 10 mounted on the semiconductor circuit device substrate 81.

The semiconductor pressure sensor device 10 includes a glass substrate 61 and an MEMS (Micro Electro Mechanical Systems) sensor chip (sensor part) 60 mounted on the glass substrate 61. The glass substrate 61 seals a space surrounded by a frame part 61a of the MEMS sensor chip 60 by performing anodic bonding between a bottom surface of the frame part 61a and an upper surface of the glass substrate 61. The MEMS sensor chip 60 is a pressure sensor part of the sensor apparatus having substantially the same configuration as the configuration of the above-described embodiment of the semiconductor pressure sensor device 11.

Similar to the above-described resist spacer 52, one or more glass spacers 62 are interposed between an attachment surface 61a1 of the glass substrate 61 and a mounting surface 81A of the semiconductor circuit device substrate 81. The glass spacer 62 may have substantially the same configuration as the above-described embodiment of the resist spacer 52. In this embodiment, the glass spacers 62 are formed of two glass spacers 62a, 62c positioned facing each other in the X direction and two glass spacers 62b, 62d (not illustrated).

Before bonding the bottom surface of the frame part 61a of the MEMS sensor chip 60 and the glass substrate 61 together, the glass spacers 62 are integrally formed with the attachment surface 61a1 of the glass substrate 61. More specifically, the glass spacers 62 are directly formed on the attachment surface 61a1 of the glass substrate 61 by using, for example, an etching method or a sandblasting method.

The glass spacers 62 include target attachment surfaces 62a1, 62b1, 62c1, and 62d1 that are bonded to the mounting surface 81A via the bonding resin 15. It is, however, to be noted that, although the target attachment surface 62a1 of the glass spacer 62a and the target attachment surface 62c of the glass spacer 62c1 are illustrated in FIG. 16, the target attachment surface 62b1 of the glass spacer 62b and the target attachment surface 62d1 of the glass spacer 62d are omitted in FIG. 16.

The target attachment surfaces 62a1, 62b1, 62c1, 62d1 are formed in a size that the area S3 of the attachment surface 61a1 is larger than the total area S4 of the target attachment surfaces 62a1, 62b1, 62c1, 62d1 (i.e. sum of the areas of the target attachment surfaces 62a1, 62b1, 62c1, 62d1). In other words, the total area S4 of the target attachment surfaces 62a1, 62b1, 62c1, 62d1 is smaller than the area S3 of the attachment surface 61a1. The attachment surface 61a1 has a square shape and an evenly flat surface. By forming the target attachment surfaces 62a1, 62b1, 62c1, 62d1 in a manner that the total area S4 of the target attachment surfaces 62a1, 62b1, 62c1, 62d1 is smaller than the area S3 of the attachment surface 61a1, a space can be provided below the attachment surface 61a1. In other words, because the total area S4 of the target attachment surfaces 62a1, 62b1, 62c1, 62d1 is smaller than the area 53 of the attachment surface 61a1, the die-bond resin 15 can be allowed to escape (be guided) toward the side of the glass spacers 62 when the mounting surface 81A contacts the target attachment surfaces 62a1, 62b1, 62c1, 62d1 during a die-bonding process. As a result, the die-bond resin 15 interposed between the attachment surface 61a1 and the target attachment surfaces 62a1, 62b1, 62c1, 62d1 can be prevented from becoming thicker than necessary. Accordingly, the semiconductor pressure sensor device 10 can be prevented from sinking and the wire-bonding strength can be prevented from decreasing even where ultrasonic waves, force, and heat are applied to the wire-ball 13a during a wire-bonding step.

The load applied to the die-bond resin 15 interposed between the attachment surface 61a1 and the target attachment surfaces 62a1, 62b1, 62c1, 62d1 during a wire-bonding step becomes larger in a case where the total area S4 is less than the total area S3 compared to a case where the total area S4 is greater than the total area S3. This is because the stress applied to the target attachment surfaces 62a1, 62b1, 62c1, 62d1 increases if the load of mounting the semiconductor pressure sensor device 10 on the semiconductor circuit device substrate 81 during a die-bonding step where the total area S4 is less than the total area S3 is the same as the load of mounting the semiconductor pressure sensor device 10 on the semiconductor circuit device substrate 81 during a die-bonding step where the total area S4 is greater than the total area S3. Accordingly, by forming the target attachment surfaces 62a1, 62b1, 62c1, 62d1 in a size that the total area S4 is less than the total area S3, the thickness of the die-bond resin 15 interposed between the attachment surface 61a1 and the target attachment surface 62a1, 62b1, 62c1, 62d1 can be reduced. As a result, the semiconductor pressure sensor device 10 can be prevented from sinking and the wire-bonding strength can be prevented from decreasing even where ultrasonic waves, force, and heat are applied to the wire-ball 13a during a wire-bonding step.

Although the glass spacers 62 are integrally formed with the glass substrate 61 in the above-described embodiment, the glass spacers 62 may be formed as glass components that are separate from the glass substrate 61. Further, the glass spacers 62 in the above-described embodiment are formed of a glass material, the glass spacers 62 may be replaced with other spacers formed of a material other than glass. For example, the glass spacers 62 may be replaced with resist spacers formed on the mounting surface 81A of the semiconductor circuit device substrate 81 (i.e. resist spacers formed on the semiconductor circuit device substrate 81 in addition to the resist spacers 52 formed in the substrate 12 of FIG. 16). In the case of replacing the glass spacers 62 with the resist spacers, the target attachment surface of the resist spacers are to be adhered to the attachment surface 61a1 of the glass substrate 61 via the die-bond resin 15.

Hence, with the glass spacers 62 according to the above-described embodiment of the present invention, the bonding wires 73A connecting the wire-bonding pads 83 of the semiconductor circuit device substrate 81 and the wire-bonding pads 61c of the semiconductor pressure sensor device 10 can attain a high bonding strength (bondability). Further, the wire-bonding pad 61c is formed at the peripheral part of the diaphragm 61b in a manner that the wire-bonding pad 61c is positioned on a line normal to at least one of the target attachment surfaces 62a1-62d1 in a state where the semiconductor pressure sensor device 10 is mounted on the semiconductor circuit device substrate 81. An example of the line normal to the target attachment surfaces 62c1 is illustrated with a dotted line in FIG. 16. Thereby, the bonding strength of the bonding wires 73A can be further increased.

Further, the bonding wires 73B can attain a high bonding strength between the wire-bonding pads 82 of the semiconductor circuit device substrate 81 and the wire-bonding pads 14 of the substrate 12 owing to the resist spacers 52 (52a-52d) because the resist spacers 52 (52a-52d) are formed in a size so that a total area S5 of the target attachment surfaces 52a1-52d1 of the resist spacers 52 (52a-52d) is less than an area. S6 of the attachment surface 81B on the bottom side of the semiconductor circuit device substrate 81. Further, the wire-bonding pad 61c is formed at the peripheral part of the diaphragm 61b in a manner that the wire-bonding pad 61c is positioned on a line normal to at least one of the target attachment surfaces 52a1-52d1 in a state where the semiconductor circuit device substrate 81 is mounted on the substrate 12. Thereby, the bonding strength of the bonding wires 73A can be further increased.

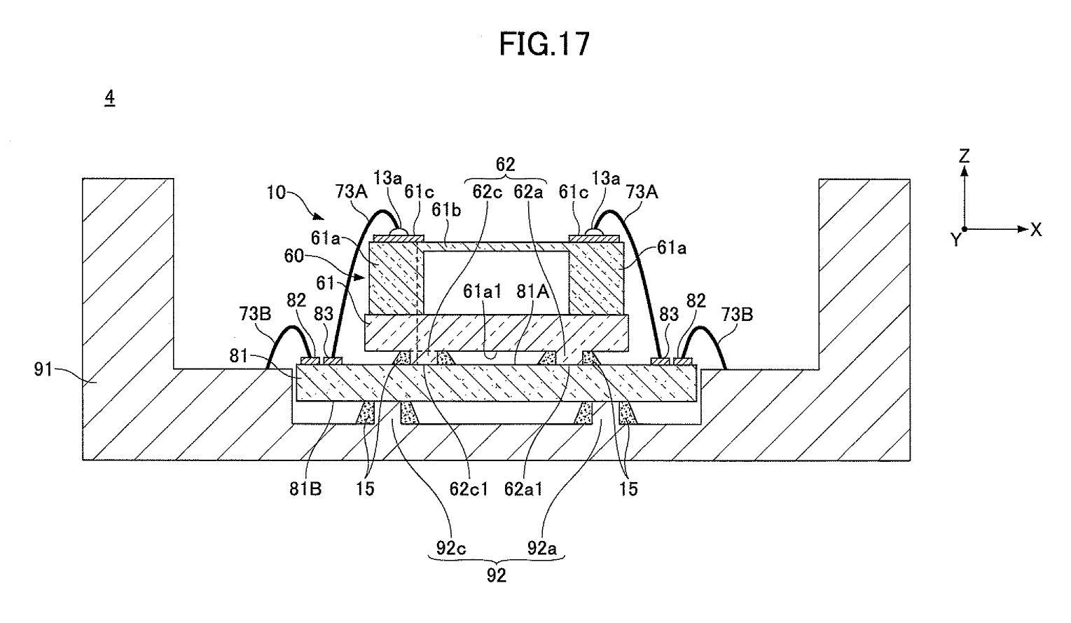

FIG. 17 is a cross-sectional view of a sensor apparatus 4 (e.g., pressure sensor apparatus) according to another embodiment of the present invention. In FIG. 17, like components are denoted with like reference numerals as those of the above-described embodiments of the present invention. In this embodiment, the pressure sensor device 4 has a stacked structure adhered to a ceramic package 91. The stacked structure includes the semiconductor circuit device substrate 81 and the semiconductor pressure sensor device 10 mounted on the semiconductor circuit device substrate 81.

The wire-bonding between the semiconductor pressure sensor device 10 and the semiconductor circuit device substrate 81 and the wire bonding between the semiconductor circuit device substrate 81 and the ceramic package 91 are substantially the same as the above-described embodiment illustrated in FIG. 16. In this embodiment, the bonding wires 73B can attain a high bonding strength between the semiconductor circuit device substrate 81 and ceramic package 91 owing to the ceramic spacers 92 (92a-92d) because the ceramic spacers 92 (92a-92d) are integrally formed with the ceramic package 91 inside the ceramic package 91.

Similar to the above-described embodiments of the resist spacers 52 and the glass spacers 62, the ceramic spacers 92, the die-bond resin 15 interposed between the attachment surface 81B and the target attachment surfaces 92a1, 92b1, 92c1, 92d1 of the ceramic spacers 92 (92a-92d) can be prevented from becoming thicker than necessary. As a result, the semiconductor pressure sensor device 10 can be prevented from sinking and the wire-bonding strength can be prevented from decreasing even where ultrasonic waves, force, and heat are applied to the wire-ball 13a during a wire-bonding step.

Further, the present invention is not limited to these embodiments, but variations and modifications may be made without departing from the scope of the present invention.

The present application is based on Japanese Priority Application Nos. 2010-194636 and 2011-176062 filed on Aug. 31, 2010 and Aug. 11, 2011, with the Japanese Patent Office, the entire contents of which are hereby incorporated by reference.

What is claimed is:

1. A sensor apparatus comprising:
a semiconductor sensor device including a first attachment surface;
a base part being wire-bonded to the semiconductor sensor device and including a second attachment surface; and
a spacer being interposed between the first and second attachment surfaces and having a target attachment surface to which at least one of the first and second attachment surfaces is adhered via a die-bond resin;
wherein a total area of the target attachment surface is smaller than a total area of the first attachment surface.

2. The sensor apparatus as claimed in claim 1, wherein the semiconductor sensor device includes a wire-bonding area to which the base part is wire-bonded, and
wherein the wire-bonding area is positioned in a direction of a line normal to the target attachment surface.

3. The sensor apparatus as claimed in claim 2, wherein the semiconductor sensor device further includes a glass substrate and a sensor part bonded to the glass substrate,
wherein the first attachment surface is formed on a surface of the glass substrate, and
wherein the wire-bonding area is formed on a surface of the sensor part.

4. The sensor apparatus as claimed in claim 1, wherein the spacer is formed on the base part.

5. The sensor apparatus as claimed in claim 4, wherein the spacer is a part of a resist layer formed on the base part.

6. The sensor apparatus as claimed in claim 3, wherein the spacer is formed on a surface of the semiconductor sensor device.

7. The sensor apparatus as claimed in claim 1, wherein the base part includes a pressure inlet configured to introduce pressure to the semiconductor sensor device, wherein the spacer is provided at a periphery of the pressure inlet.

8. A method for mounting a semiconductor sensor device comprising the steps of:
applying a die-bond resin on a target attachment surface of a spacer;
die-bonding the target attachment surface to at least one of a first attachment surface of the semiconductor device and a second attachment surface of a base part via the die-bond resin applied on the target attachment surface; and
wire-bonding the semiconductor sensor device and the base part via a wire;
wherein the spacer is positioned between the first and second attachment surfaces, and
wherein a total area of the target attachment surface is smaller than a total area of the first attachment surface.
